(19) United States
(12) Patent Application Publication
(10) Pub. No.: US 2024/0123673 A1
(43) Pub. Date: Apr. 18, 2024

(54) METHOD OF MANUFACTURING DISPLAY DEVICE

(71) Applicant: Samsung Display Co., LTD., Yongin-si (KR)

(72) Inventors: DONGWOO KIM, Yongin-si (KR); SANGHOON PARK, Yongin-si (KR); HEE SOO HAN, Yongin-si (KR)

(21) Appl. No.: 18/225,195

(22) Filed: Jul. 24, 2023

(30) Foreign Application Priority Data
Oct. 17, 2022 (KR) 10-2022-0133629

(51) Int. Cl. B29C 53/04; G06T 7/00; G06T 7/33; G06T 7/73

(52) U.S. Cl. CPC B29C 53/04; G06T 7/001; G06T 7/337; G06T 7/74; B29L 2031/3475; G06T 2207/30108; G06T 2207/30204

(57) ABSTRACT

A method of manufacturing a display device includes: disposing a member having a first alignment mark and a second alignment mark spaced apart from the first alignment mark on a stage; adsorbing the member to an upper surface of the stage; capturing an image of the member with a camera disposed on the stage; comparing a captured phase of the second alignment mark with a first preset phase of the second alignment mark; adsorbing the member to a bending part disposed apart from the stage; and bending the member with the bending part.

This application claims priority to Korean Patent Application No. 10-2022-0133629, filed on Oct. 17, 2022, and all the benefits accruing therefrom under 35 U.S.C. § 119, the content of which in its entirety is herein incorporated by reference.

### BACKGROUND

### 1. Field

Embodiments relate to a method of manufacturing a display device. More specifically, embodiments relate to a method of manufacturing a display device that provides visual information.

### 2. Description of the Related Art

A circuit film may be used in a display device. A bendable circuit film is used to reduce a bezel area of the display device. A flexible printed circuit board and the like is used as the bendable circuit film. When the flexible printed circuit board attached to a substrate is bent, stress may act on a portion where the flexible printed circuit board is attached to the substrate.

### SUMMARY

Embodiments provide a method of manufacturing a display device with improved productivity.

A method of manufacturing a display device according to an embodiment of the present disclosure includes: disposing a member having a first alignment mark and a second alignment mark spaced apart from the first alignment mark on a stage, adsorbing the member to an upper surface of the stage, capturing an image of the member with a camera disposed on the stage, comparing a captured phase of the second alignment mark with a first preset phase of the second alignment mark, adsorbing the member to a bending part disposed apart from the stage, and bending the member with the bending part.

In an embodiment, in the bending of the member with the bending part, a bending path of the bending part may be varied based on comparison of the captured phase of the second alignment mark with the first preset phase of the second alignment mark.

In an embodiment, in the bending of the member with the bending part, the second alignment mark may be moved to a second preset phase of the second alignment mark when the bending part is bent along the bending path.

In an embodiment, the first preset phase of the second alignment mark may be a preset phase before bending the bending part, and the second preset phase of the second alignment mark may be a preset phase after bending the bending part.

In an embodiment, the member may include a panel defining a first area and a second area adjacent to the first area and a flexible printed circuit board connected to the panel.

In an embodiment, in the adsorbing of the member to the upper surface of the stage, the first area of the panel may be adsorbed to the upper surface of the stage.

In an embodiment, the first alignment mark may be formed in the first area of the panel, and the second alignment mark may be formed in the second area of the panel.

In an embodiment, the method may further include comparing a captured phase of the first alignment mark with a preset phase of the first alignment mark.

In an embodiment, in the bending of the member with the bending part, a bending path of the bending part may be varied based on comparison of the captured phase of the first alignment mark with the preset phase of the first alignment mark.

In an embodiment, the camera may simultaneously capture the first alignment mark and the second alignment mark.

In an embodiment, the capturing of the member may include capturing the first alignment mark and the second alignment mark with the camera, comparing a captured position of the first alignment mark with a preset position of the first alignment mark, and rotating the stage so that the captured position of the first alignment mark overlaps the preset position of the first alignment mark in a plan view.

In an embodiment, the member may include a first surface and a second surface facing the first surface, and the second surface may be adsorbed by the upper surface of the stage.

In an embodiment, the first alignment mark and the second alignment mark may be formed on the first surface of the member.

In an embodiment, the bending of the member with the bending part may include: attaching a first portion of the first surface overlapping the bending part to a second portion of the first surface adjacent to the first portion of the first surface.

A method of manufacturing a display device according to an embodiment of the present disclosure includes: disposing a member having a first alignment mark and a second alignment mark spaced apart from the first alignment mark on a stage, adsorbing the member to an upper surface of the stage, capturing an image of the member with a camera disposed on the stage, comparing a captured phase of the second alignment mark with a preset phase of the second alignment mark, adsorbing the member to a bending part disposed apart from the stage, and moving the member by the bending part so that the captured phase of the second alignment mark overlaps the preset phase of the second alignment mark in a plan view.

In an embodiment, in the moving of the member, the bending part may be adjusted so that the member has a flat upper surface.

In an embodiment, the method may further include bending the member with the bending part.

In an embodiment, the member may include a panel defining a first area and a second area adjacent to the first area and a flexible printed circuit board connected to the panel.

In an embodiment, the first alignment mark may be formed in the first area of the panel, and the second alignment mark may be formed in the second area of the panel.

In an embodiment, the camera may simultaneously capture the first alignment mark and the second alignment mark.

In a method of manufacturing a display device according to embodiments of the present disclosure, the method may include comparing a captured phase of a second alignment mark before bending with a first preset phase of the second alignment mark. By comparing the phases of the second alignment mark, an adsorption state of a member may be estimated, and a bending path of a bending part may be changed to an optimal bending path based on the estimated adsorption state. Accordingly, since the member may be realigned one or less time after bending is completed, an efficiency of a bending process may be increased and productivity may be effectively increased.

### BRIEF DESCRIPTION OF THE DRAWINGS

FIG. 1 is a front view illustrating an apparatus for manufacturing a display device.

FIG. 2 is a plan view illustrating the apparatus for manufacturing a display device of FIG. 1.

FIGS. 3, 4, 5, 6, 7 and 8 are diagrams for explaining an example of a method of manufacturing a display device using the apparatus of FIG. 1.

FIG. 9 is a diagram for explaining another example of FIG. 3.

FIG. 10 is a diagram for explaining another example of FIG. 6.

FIGS. 11, 12 and 13 are diagrams for explaining another example of a method of manufacturing a display device using the apparatus of FIG. 1.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Hereinafter, embodiments of the present disclosure will be described in more detail with reference to the accompanying drawings. The same reference numerals are used for the same components in the drawings, and redundant descriptions of the same components will be omitted.

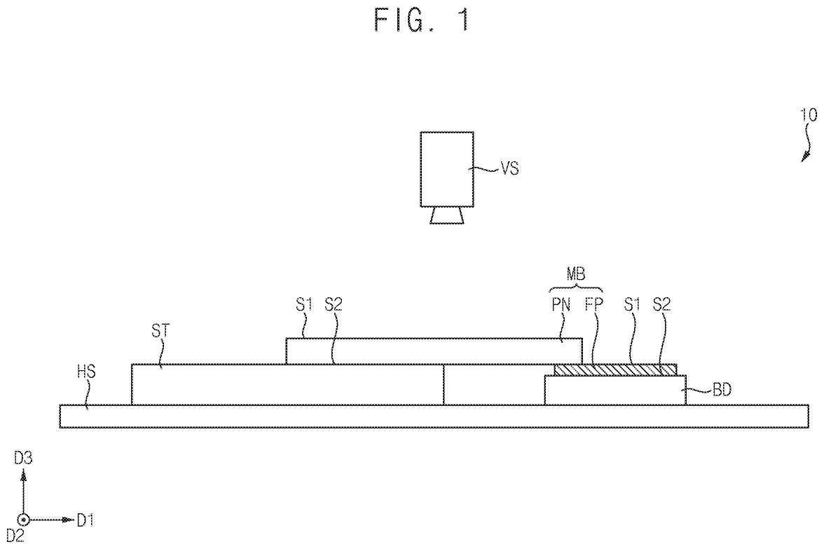

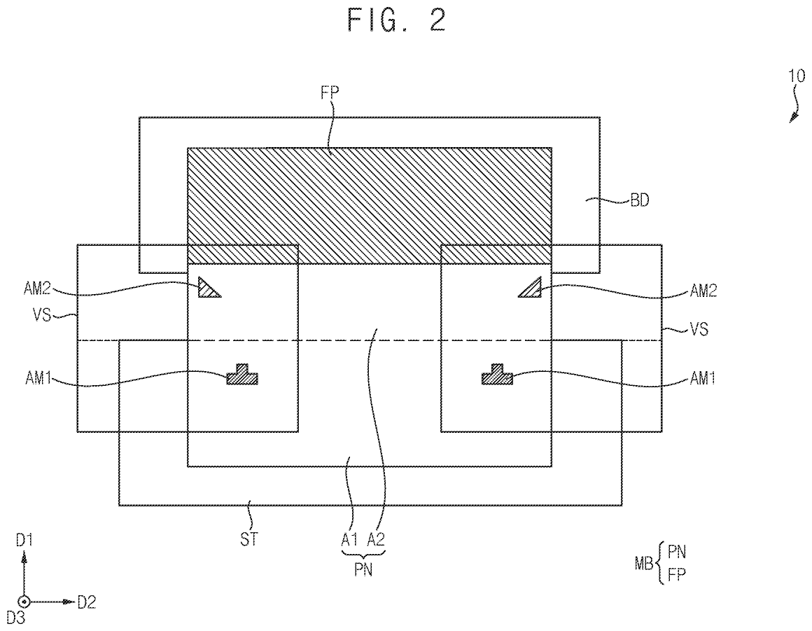

FIG. 1 is a front view illustrating an apparatus for manufacturing a display device. FIG. 2 is a plan view illustrating the apparatus for manufacturing the display device of FIG. 1. Here, the plan view is a view in a third direction DR3 (i.e., the direction in which the camera VS captures the marks AM1 and AM2).

Referring to FIGS. 1 and 2, an apparatus 10 for manufacturing a display device may include a housing HS, a stage ST, a bending part BD and a camera VS.

The housing HS may be installed to be fixed to an outside. The housing HS may include a plurality of frames, plates and the like. The housing HS may be formed in a chamber shape.

The stage ST may be disposed on the housing HS. The stage ST may include a top surface parallel to a plane defined by a first direction D1 and a second direction D2 crossing the first direction D1. For example, the first direction D1 and the second direction D2 may be perpendicular to each other. That is, the stage ST may be formed in a plate shape. In an embodiment, the stage ST may linearly move in the first direction D1.

The bending part BD may be disposed on the housing HS. The bending part BD may be disposed apart from the stage ST in the first direction D1. The bending part BD may bend a member MB along a bending path. For example, the bending part BD may adsorb a portion of a second surface S2 of the member MB to bend the member MB, and may attach a portion of a first surface S1 of the member MB to another portion of the first surface S1 of the member MB.

In an embodiment, the bending path of the bending part BD may be varied. For example, the bending path of the member MB may be set in consideration of a type of member MB, a position of the member MB, an adsorption state of the member MB, a stress applied to the member MB during bending, and the like. At this time, the bending path may be set in advance in a form of a table in consideration of the above conditions and the like.

The member MB may be disposed on the stage ST and the bending part BD. In other words, the member MB may be adsorbed to an upper surface of the stage ST and the bending part BD. The member MB may include the first surface S1 and the second surface S2. The second surface S2 may face the first surface S1, and may be adsorbed by the upper surface of the stage ST and the bending part BD. For example, the member MB may have various shapes.

In an embodiment, the member MB may include a panel PN and a flexible printed circuit board FP connected to the panel PN. A first area A1 and a second area A2 adjacent to the first area A1 may be defined on the panel PN. The first area A1 may be an area adsorbed by the upper surface of the stage ST, and the second area A2 may be an area bent by the bending part BD. In addition, the flexible printed circuit board FP may be connected to the second area A2, and may be adsorbed by the bending part BD.

A first alignment mark AM1 and a second alignment mark AM2 spaced apart from the first alignment mark AM1 may be formed on the panel PN. For example, the first alignment mark AM1 and the second alignment mark AM2 may be formed on the first surface S1 (e.g., upper surface) of the panel PN. Specifically, the first alignment mark AM1 may be formed on the first surface S1 of the first area A1 of the panel PN, and second alignment mark AM2 may be formed on the first surface S1 of the second area A2 of the panel PN. The first alignment mark AM1 and the second alignment mark AM2 may have different shapes. However, the present disclosure is not limited thereto.

The camera VS may be disposed spaced apart from the stage ST in a third direction D3 perpendicular to each of the first direction D1 and the second direction D2. The camera VS may detect the member MB disposed on the stage ST and the bending part BD. Specifically, the camera VS may capture the first alignment mark AM1 and the second alignment mark AM2 formed on the first surface S1 of the member MB. For example, the camera VS may simultaneously capture the first alignment mark AM1 and the second alignment mark AM2. In addition, the camera VS may capture the member MB, and may transmit a captured image to the outside. The camera VS may be a vision system. The camera VS may include two cameras to capture both the left image and the right image as shown in FIG. 2.

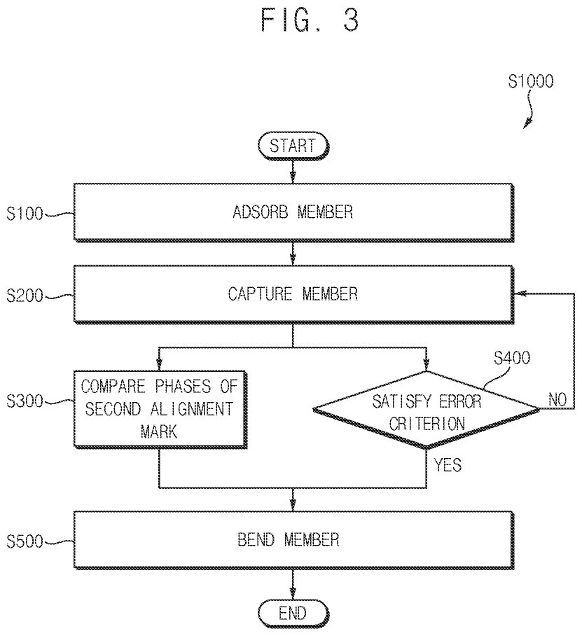

FIGS. 3, 4, 5, 6, 7 and 8 are diagrams for explaining an example of a method of manufacturing a display device using the apparatus of FIG. 1.

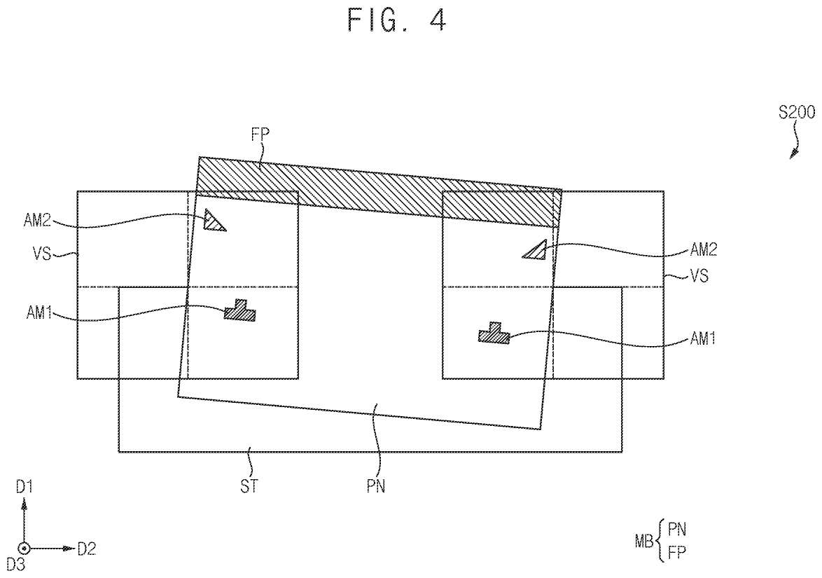

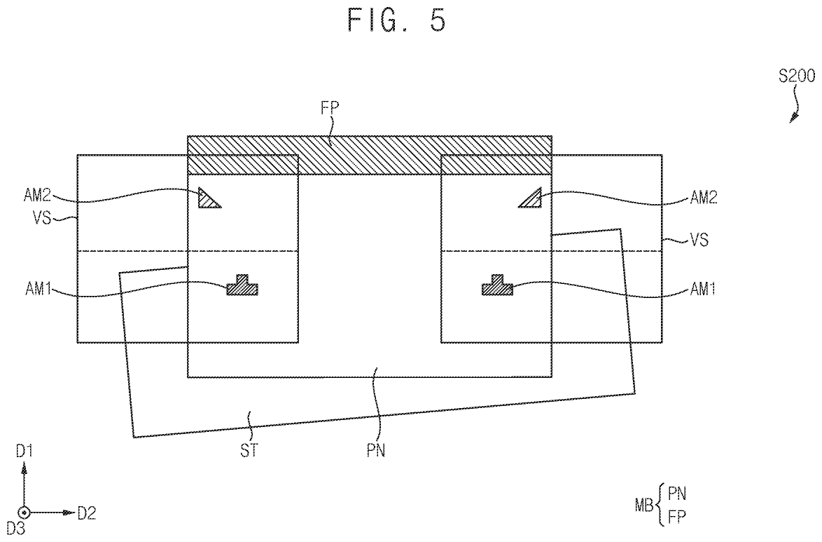

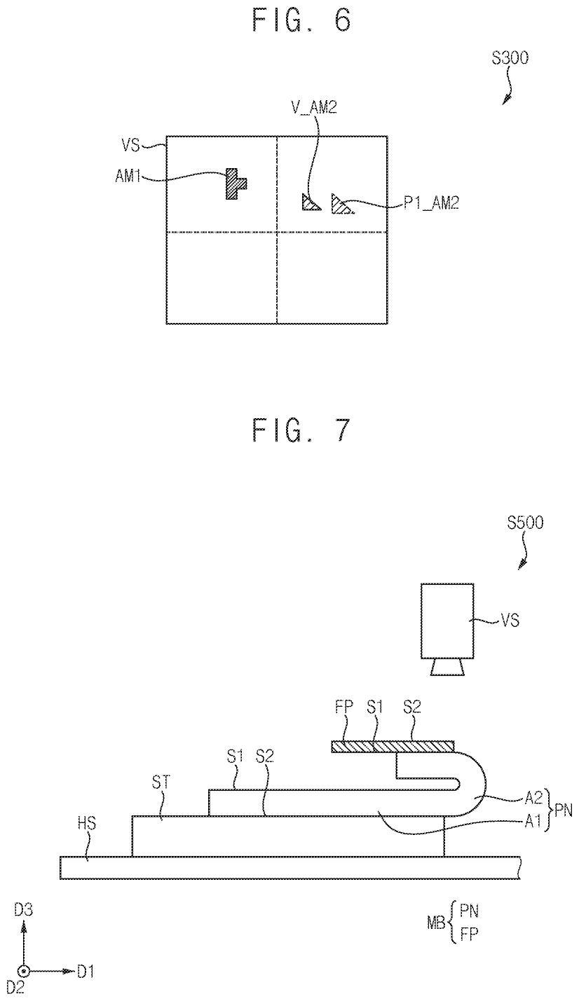

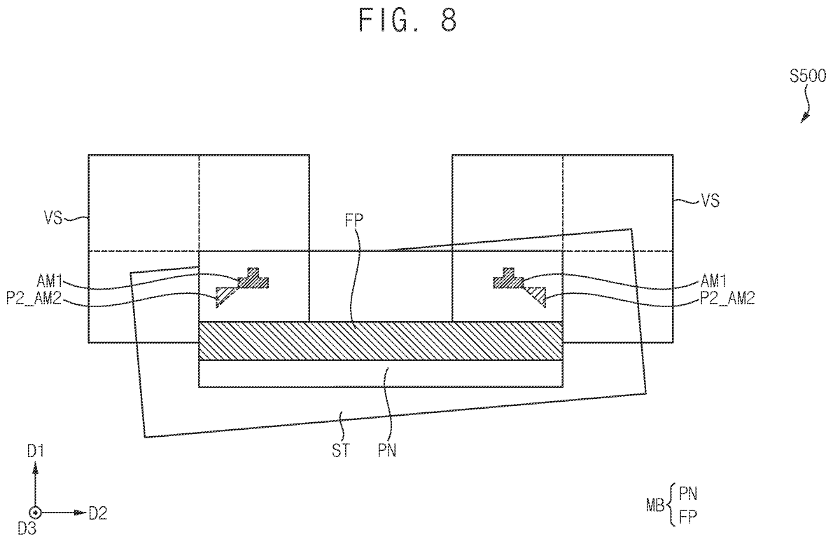

For example, FIG. 3 may be a flowchart for explaining a method (S1000) of manufacturing a display device using the apparatus 10 of FIG. 1, and FIGS. 4 and 5 may be diagrams for explaining a process (S200) of capturing a member with a camera of FIG. 3. FIG. 6 may be a diagram for explaining a process (S300) of comparing phases of a second alignment mark of FIG. 3, and FIGS. 7 and 8 may be diagrams for explaining a process (S500) of bending the member with a bending part.

Referring to FIGS. 1 and 3, in the method (S1000) of manufacturing the display device using the apparatus 10, the member MB may be adsorbed to the stage ST (S100). For example, the second surface S2 (e.g., lower surface) of the panel PN included in the member MB may be adsorbed to the upper surface of the stage ST.

Referring to FIGS. 1, 3, 4 and 5, in the method (S1000) of manufacturing the display device, the camera VS may capture the member MB disposed on the stage ST (S200). Specifically, the camera VS may simultaneously capture the first alignment mark AM1 and second alignment mark AM2 formed on the first surface S1 of the member MB (see FIG. 4). Then, by comparing a captured position of the first alignment mark AM1 with a preset position of the first alignment mark AM1, the stage ST may be moved or rotated so that the position of the first alignment mark AM1 and the preset position of the first alignment mark AM1 overlap (see FIG. 5). For example, the stage ST may move or be rotated on the plane defined by the first direction D1 and the second direction D2.

Referring to FIGS. 3 and 6, in the method (S1000) of manufacturing the display device, phases of the second alignment mark AM2 may be compared (S300). In an embodiment, a captured phase V_AM2 of the second alignment mark AM2 by the camera VS and a first preset phase P1_AM2 of the second alignment mark AM2 may be compared. For example, captured position and shape of the second alignment mark AM2 by the camera VS and first preset position and shape of the second alignment mark AM2 in a plan view may be compared. In this case, the first preset phase P1_AM2 of the second alignment mark AM2 may be a preset phase before bending the bending part BD.

In another embodiment, an additional process of comparing a captured phase of the first alignment mark AM1 by the camera VS and a preset phase of the first alignment mark AM1 may be further performed.

In the method (S1000) of manufacturing the display device, it may be determined whether difference between the position of the first alignment mark AM1 by the camera VS and the preset position of the first alignment mark AM1 satisfy an error criterion after the stage ST is moved or rotated (S400).

In an embodiment, comparing the phases of the second alignment mark AM2 (S300) and determining whether the position of the first alignment mark AM1 satisfies the error criterion (S400) may be performed simultaneously.

Referring to FIGS. 3, 7 and 8, in the method (S1000) of manufacturing the display device, the bending part BD may bend the member MB (S500). The bending part BD may adsorb a portion of the second surface S2 of the member MB to bend the member MB along the bending path. For example, the bending part BD may adsorb the second surface S2 of the flexible printed circuit board FP to bend the second area A2 of the panel PN, and the flexible printed circuit board FP may be moved to an upper side of the first area A1 of the panel PN. A separate adhesive member (not shown) may be disposed on the first surface S1 of the member MB, and thus, a portion of the first surface S1 of the member MB may be attached to another portion of the first surface S1 of the member MB. For example, a portion of the first surface S1 of the second area A2 of the panel PN may be attached to a portion of the first surface S1 of the first area A1 of the panel PN (See FIG. 7).

In an embodiment, the bending path of the bending part BD may be varied based on the comparison of the captured phase V_AM2 of the second alignment mark AM2 and the first preset phase P1_AM2 of the second alignment mark AM2. Then, when the bending part BD is bent along the bending path, the second alignment mark AM2 formed on the panel PN may be moved to a second preset phase P2_AM2 of the second alignment mark AM2 (see FIG. 8) in a plan view. In this case, the second preset phase P2_AM2 of the second alignment mark AM2 may be a preset phase where the second alignment mark AM2 should go after bending the bending part BD.

In another embodiment, the bending path of the bending part BD may be varied by further comparing the captured phase of the first alignment mark AM1 and the preset phase of the first alignment mark AM1.

After bending the member MB is completed, the camera VS may capture the member MB disposed on the stage ST. Specifically, the camera VS may simultaneously capture the first alignment mark AM1 and the second alignment mark AM2 formed on the first surface S1 of the member MB. By comparing the captured phase of the first alignment mark AM1 with the preset phase of the first alignment mark AM1 and comparing the captured phase of the second alignment mark AM2 with the second preset phase P2_AM2 of the second alignment mark AM2, it may be determined whether an error criterion is satisfied.

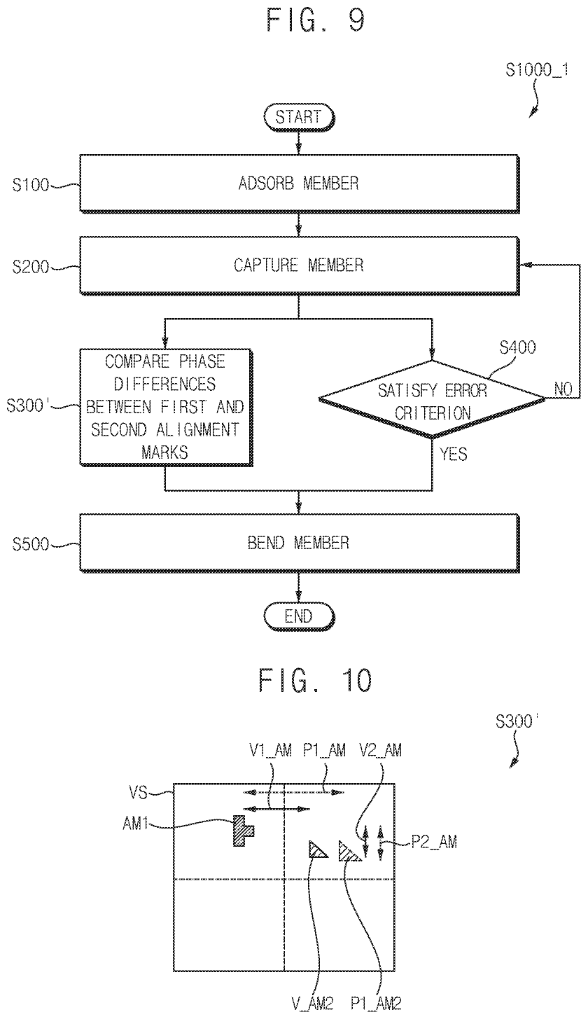

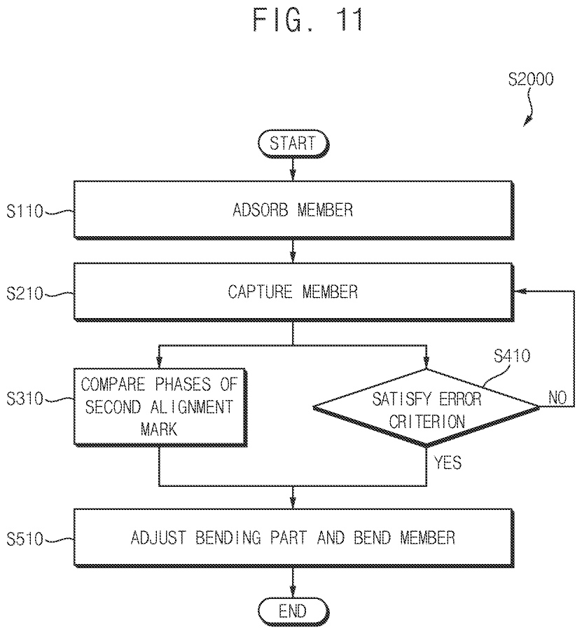

FIG. 9 is a diagram for explaining another example of FIG. 3. FIG. 10 is a diagram for explaining another example of FIG. 6. For example, FIG. 9 may be a flowchart for explaining another method (S1000_1) of manufacturing the display device using the apparatus 10 of FIG. 1, and FIG. 10 may be a diagram for explaining a process (S300′) of comparing phase differences between a first alignment mark AM1 and a second alignment mark AM2 of FIG. 9.

Hereinafter, a description overlapping with the method (S1000) of manufacturing the display device described with reference to FIGS. 3 and 6 will be omitted or simplified.

Referring to FIGS. 9 and 10, in the method (S1000_1) of manufacturing the display device, the phase differences between a first alignment mark AM1 and a second alignment mark AM2 may be compared (S300′). Specifically, “captured” phase differences V1_AM and V2_AM between the first alignment mark AM1 and the second alignment mark AM2 and “preset ‘phase differences P1_AM and P2_AM between the first alignment mark AM1 and the second alignment mark AM2 may be compared. The captured phase differences V1_AM and V2_AM are phase differences between the first alignment mark AM1 and the captured phase V_AM2 of the second alignment mark AM2 in one direction and another direction perpendicular to the one direction, and the preset phase differences P1_AM and P2_AM are phase differences between the first alignment mark AM1 and the first preset phase P1_AM2 of the second alignment mark AM2 in one direction and another direction perpendicular to the one direction.

In an embodiment, the bending path of the bending part BD may be varied based on comparison of the captured phase differences V1_AM and V2_AM with the preset phase differences P1_AM and P2_AM. Then, when the bending part BD is bent along the bending path, the second alignment mark AM2 may be moved to the second preset phase P2_AM2 of the second alignment mark AM2.

In the method (S1000_1) of manufacturing of the display device according to an embodiment of the present disclosure, the bending path of the bending part BD may be varied to an optimal bending path by comparing the captured phase V_AM2 of the second alignment mark AM2 before bending with the first preset phase P1_AM2 of the second alignment mark AM2 to estimate an adsorption state of the member MB. Accordingly, since the member MB may be realigned one or less time after bending is completed, an efficiency of a bending process may be increased and productivity may be effectively increased.

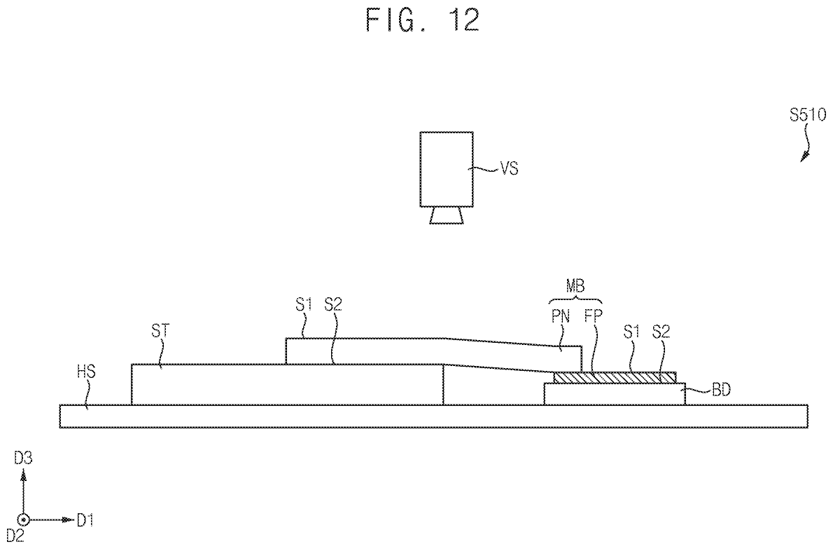

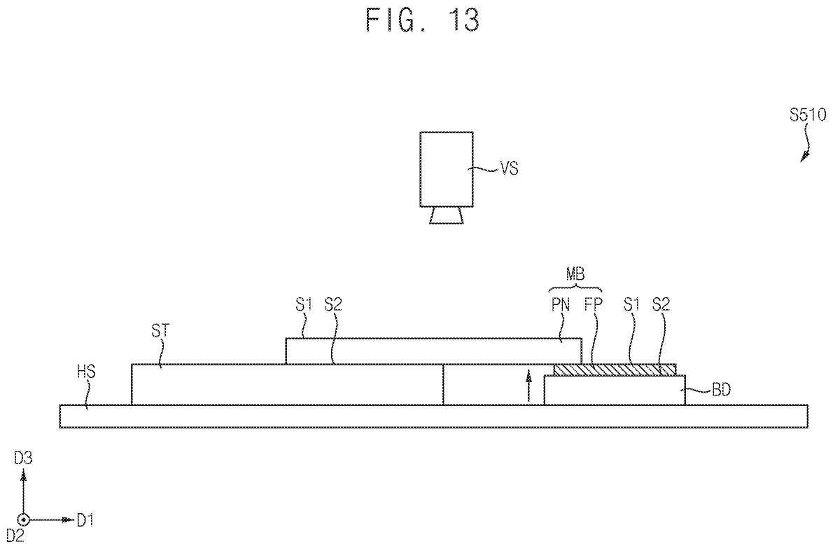

FIGS. 11, 12 and 13 are diagrams for explaining another example of a method of manufacturing a display device using the apparatus of FIG. 1. For example, FIG. 11 may be a flowchart for explaining a method of manufacturing a display device (S2000) using the apparatus 10 of FIG. 1, and FIGS. 12 and 13 may be diagrams for explaining a process (S510) of bending a member with a bending part of FIG. 11.

Hereinafter, descriptions overlapping with those of the method (S1000) of manufacturing the display device described with reference to FIG. 3 will be omitted or simplified.

Referring to FIGS. 2 and 11, in the method of manufacturing the display device (S2000) using the apparatus 10, the member MB may be adsorbed to the stage ST (S110), and the camera VS may capture the member MB disposed on the stage ST (S210). Specifically, the camera VS may simultaneously capture the first alignment mark AM1 and the second alignment mark AM2 formed on the member MB, so that the captured position of the first alignment mark AM1 by the camera VS and the preset position of the first alignment mark AM1 may be compared.

In the method of manufacturing the display device (S2000), a captured phase of the second alignment mark AM2 (e.g., the captured phase V_AM2 in FIG. 6) and a first preset phase of the second alignment mark AM2 (e.g., the first preset phase P1_AM2 in FIG. 6) may be compared (S310). In addition, after the stage ST is moved or rotated, it may be determined whether the difference between the position of the first alignment mark AM1 and the preset position of the first alignment mark AM1 satisfy an error criterion (S410). In an embodiment, comparing the phases of the second alignment mark AM2 (S310) and determining whether the position of the first alignment mark AM1 satisfies the error criterion (S410) may be performed simultaneously.

Referring to FIGS. 2, 11, 12 and 13, in the method of manufacturing the display device (S2000), the bending part BD may be adjusted and bend the member MB (S510). In an embodiment, the bending part BD may move the member MB based on comparison of the captured phase of the second alignment mark AM2 with the first preset phase of the second alignment mark AM2. Specifically, the bending part BD may move the member MB so that the captured phase of the second alignment mark AM2 and the first preset phase of the second alignment mark AM2 overlap in a plan view. That is, the bending part BD may be adjusted so that the member MB has a “flat” upper surface (see FIGS. 12 and 13). For example, a height of the bending part BD may be adjusted, a distance between the bending part BD and the stage ST may be adjusted, and an inclination of the bending part BD may be adjusted, but the present disclosure is not limited to this.

Then, the bending part BD may bend the member MB along a preset bending path, and the second alignment mark AM2 may be moved to a second preset phase (e.g., the second preset phase P2_AM2 of FIG. 8) of the second alignment mark AM2.

In the method of manufacturing of the display device (S2000) according to an embodiment of the present disclosure, by comparing the captured phase of the second alignment mark AM2 before bending with the first preset phase of the second alignment mark AM2 to estimate an adsorption state of the member MB, the bending part BD may move the member MB to a preset position in advance. Accordingly, since the member MB may be realigned one or less time after bending is completed, an efficiency of the bending process may be increased and productivity may be increased.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A method of manufacturing a display device, the method comprising:
disposing a member having a first alignment mark and a second alignment mark spaced apart from the first alignment mark on a stage;
adsorbing the member to an upper surface of the stage;
capturing an image of the member with a camera disposed on the stage;
comparing a captured phase of the second alignment mark with a first preset phase of the second alignment mark;
adsorbing the member to a bending part disposed apart from the stage; and
bending the member with the bending part.

2. The method of claim 1, wherein in the bending of the member with the bending part, a bending path of the bending part is varied based on comparison of the captured phase of the second alignment mark with the first preset phase of the second alignment mark.

3. The method of claim 2, wherein in the bending of the member with the bending part, the second alignment mark is moved to a second preset phase of the second alignment mark when the bending part is bent along the bending path.

4. The method of claim 3, wherein the first preset phase of the second alignment mark is a preset phase before bending the bending part, and
the second preset phase of the second alignment mark is a preset phase after bending the bending part.

5. The method of claim 1, wherein the member includes a panel defining a first area and a second area adjacent to the first area and a flexible printed circuit board connected to the panel.

6. The method of claim 5, wherein in the adsorbing of the member to the upper surface of the stage, the first area of the panel is adsorbed to the upper surface of the stage.

7. The method of claim 5, wherein the first alignment mark is formed in the first area of the panel, and
the second alignment mark is formed in the second area of the panel.

8. The method of claim 1, further comprising:
comparing a captured phase of the first alignment mark with a preset phase of the first alignment mark.

9. The method of claim 8, wherein in the bending of the member with the bending part, a bending path of the bending part is varied based on comparison of the captured phase of the first alignment mark with the preset phase of the first alignment mark.

10. The method of claim 1, wherein the camera simultaneously captures the first alignment mark and the second alignment mark.

11. The method of claim 1, wherein the capturing of the member includes:
capturing the first alignment mark and the second alignment mark with the camera;
comparing a captured position of the first alignment mark with a preset position of the first alignment mark; and
rotating the stage so that the captured position of the first alignment mark overlaps the preset position of the first alignment mark in a plan view.

12. The method of claim 1, wherein the member includes a first surface and a second surface facing the first surface, and the second surface is adsorbed by the upper surface of the stage.

13. The method of claim 12, wherein the first alignment mark and the second alignment mark are formed on the first surface of the member.

14. The method of claim 12, wherein the bending of the member with the bending part includes:
attaching a first portion of the first surface overlapping the bending part to a second portion of the first surface adjacent to the first portion of the first surface.

15. A method of manufacturing a display device, the method comprising:
disposing a member having a first alignment mark and a second alignment mark spaced apart from the first alignment mark on a stage;
adsorbing the member to an upper surface of the stage;
capturing an image of the member with a camera disposed on the stage;
comparing a captured phase of the second alignment mark with a preset phase of the second alignment mark;
adsorbing the member to a bending part disposed apart from the stage; and
moving the member by the bending part so that the captured phase of the second alignment mark overlaps the preset phase of the second alignment mark in a plan view.

16. The method of claim 15, wherein in the moving of the member, the bending part is adjusted so that the member has a flat upper surface.

17. The method of claim 15, further comprising:
bending the member with the bending part.

18. The method of claim 15, wherein the member includes a panel defining a first area and a second area adjacent to the first area and a flexible printed circuit board connected to the panel.

19. The method of claim 18, wherein the first alignment mark is formed in the first area of the panel, and
the second alignment mark is formed in the second area of the panel.

20. The method of claim 15, wherein the camera simultaneously captures the first alignment mark and the second alignment mark.
